(19) United States
(12) Patent Application Publication
(10) Pub. No.: US 2026/0334048 A1
(43) Pub. Date: Oct. 22, 2026

(54) COMMON-ANODE OLED PIXEL CIRCUIT

(71) Applicant: Applied Materials, Inc., Santa Clara, CA (US)

(72) Inventors: Chun-Jan WANG, Tainan City (TW); Yu-Hsin LIN, Zhubei City (TW)

(21) Appl. No.: 19/549,876

(22) Filed: Feb. 25, 2026

Related U.S. Application Data
(60) Provisional application No. 63/764,019, filed on Feb. 27, 2025.

(51) Int. Cl. H10K 59/80; H10K 59/122

(52) U.S. Cl. CPC H10K 59/80521; H10K 59/122

(57) ABSTRACT

Embodiments described herein generally relate to displays. In one or more embodiments, a display device includes a backplane having a drain supply line (V_{DD}) and a source supply line (V_{SS}). Overhang structures are disposed over the backplane. Adjacent overhang structures define sub-pixels of the device. A plurality of sub-pixels are disposed on the backplane. Each sub-pixel includes a thin film transistor circuit including a driving thin film transistor (driving TFT). An anode is disposed on the backplane and electrically coupled to the drain supply line (V_{DD}) via a common anode interconnect. An organic light-emitting (OLE) material is disposed over the anode. A cathode is disposed over the OLE material. The cathode is electrically coupled to the driving TFT such that the driving TFT individually drives the cathode of the sub-pixel.

### CROSS-REFERENCE TO RELATED APPLICATIONS

This application claims priority to United States Provisional Patent Application 63/764,019, filed on Feb. 27, 2025 the contents of which are incorporated herein by reference.

### BACKGROUND

### Field

Embodiments described herein generally relate to displays. More specifically, embodiments described herein relate to pixel driving circuits and methods of forming pixel driving circuits for use in organic light‑emitting diode (OLED) displays, including common‑anode sub‑pixel architectures with per‑pixel cathode routing enabled by isolated overhang structures

### Description of the Related Art

Display devices are used in a variety of electronic systems. Organic light‑emitting diode (OLED) displays employ sub‑pixels in which organic layers emit light when driven by thin film transistor (TFT) circuits. OLED pixel architectures commonly use a “common cathode” configuration in which the OLED anode is driven by the pixel TFT while the cathode is tied to a shared reference, which can couple OLED voltage drift into the TFT operating point and contribute to image sticking and luminance non‑uniformity.

Accordingly, there is a need for sub‑pixel circuits and fabrication methods that realize a common‑anode architecture without requiring inverted OLED stacks, while providing per‑pixel cathode routing through electrically isolated structures to stabilize TFT biasing, reduce IR drop, and improve long‑term image quality.

### SUMMARY

Embodiments described herein generally relate to displays. More specifically, embodiments described herein relate to pixel driving circuits and methods of forming pixel driving circuits for use in organic light‑emitting diode (OLED) displays, including common‑anode sub‑pixel architectures with per‑pixel cathode routing enabled by isolated overhang structures

In one or more embodiments, a display device includes a backplane having a drain supply line (V_{DD}) and a source supply line (V_{SS}). Overhang structures are disposed over the backplane. Adjacent overhang structures define sub-pixels of the device. A plurality of sub-pixels are disposed on the backplane. Each sub-pixel includes a thin film transistor circuit including a driving thin film transistor (driving TFT). An anode is disposed on the backplane and electrically coupled to the drain supply line (V_{DD}) via a common anode interconnect. An organic light-emitting (OLE) material is disposed over the anode. A cathode is disposed over the OLE material. The cathode is electrically coupled to the driving TFT such that the driving TFT individually drives the cathode of the sub-pixel.

In one or more embodiments, a sub-pixel drive circuit includes a scan line and a data line. A switching transistor has a gate terminal coupled to the scan line. A first terminal is coupled to the data line. A second terminal is coupled to a control node. The sub-pixel drive circuit further includes a source supply line (V_{SS}) and a drain supply line (V_{DD}). A driving transistor has a gate terminal coupled to the control node. A source terminal is coupled to the V_{SS}. A drain terminal is coupled to the V_{DD}.

In one or more embodiments, a display device includes a backplane having a drain supply line (V_{DD}) and a source supply line (V_{SS}). Overhang structures are disposed over the backplane. Adjacent overhang structures define sub-pixels of the device. A first sub-pixel includes a first driving thin film transistor (driving TFT). A first anode is disposed on the backplane and electrically coupled to the drain supply line (V_{DD}) via a common anode interconnect. A first organic light-emitting (OLE) material is disposed over the first anode. A first cathode is disposed over the OLE material. The cathode is electrically coupled to the first driving TFT. A second sub-pixel includes a second driving thin film transistor (driving TFT). A second anode is disposed on the backplane and electrically coupled to the drain supply line (V_{DD}) via a common anode interconnect. A second organic light-emitting (OLE) material is disposed over the second anode. A second cathode is disposed over the second OLE material. The second cathode is electrically coupled to the second driving TFT.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a cross‑sectional view of an organic light‑emitting diode (OLED) sub‑pixel circuit, according to one or more embodiments.

FIG. 1B is a schematic cross‑sectional view of a sub-pixel of the organic light‑emitting diode (OLED) sub‑pixel circuit, according to one or more embodiments.

FIG. 2A is a schematic top view of the sub-pixel circuit, according to one or more embodiments.

FIG. 2B is a top view of the sub-pixel circuit, according to one or more embodiments.

FIG. 3 is a schematic diagram of a sub-pixel drive circuit, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to OLED display sub-pixel architectures that employ a common anode and per‑pixel cathode routing to improve drive stability, uniformity, and manufacturability. In various embodiments, each sub‑pixel includes an anode commonly coupled to a drain supply line (V_{DD}) through a backplane interconnect, an organic light‑emitting stack formed within a pixel opening, and a cathode that is individually coupled to a driving thin film transistor (TFT) referenced to a source supply line (V_{SS}). The physical implementation leverages permanent overhang structures disposed over pixel‑defining layers, where a conductive lower portion and a non‑conductive upper portion provide deposition shadowing and enable the cathode to contact the conductive sidewall for electrical routing to the driving TFT. Adjacent overhangs are separated by recesses to maintain electrical isolation between sub‑pixels. This configuration preserves a non‑inverted OLED stack, facilitates integration with n‑type oxide TFTs and compensation schemes, mitigates IR drop by consolidating hole‑injection onto a robust common anode network, and enhances long‑term image quality by stabilizing the driving TFT operating point against OLED voltage drift.

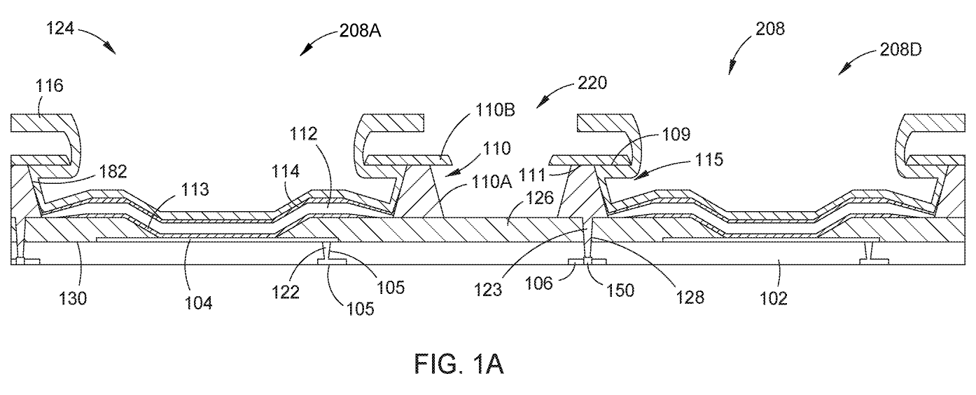

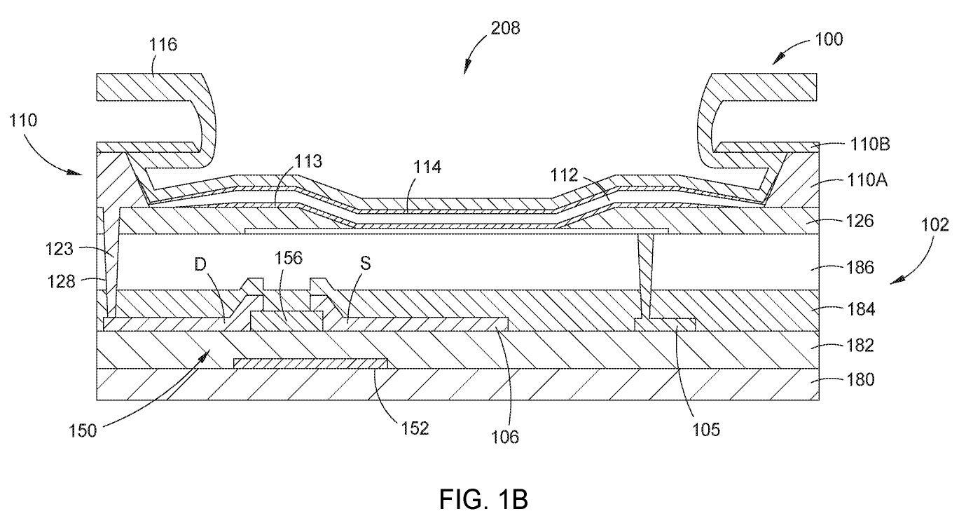

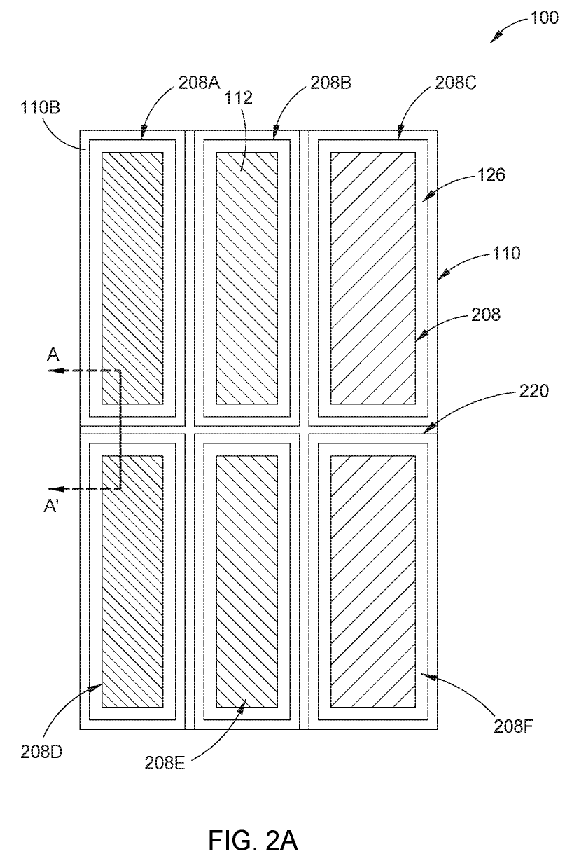

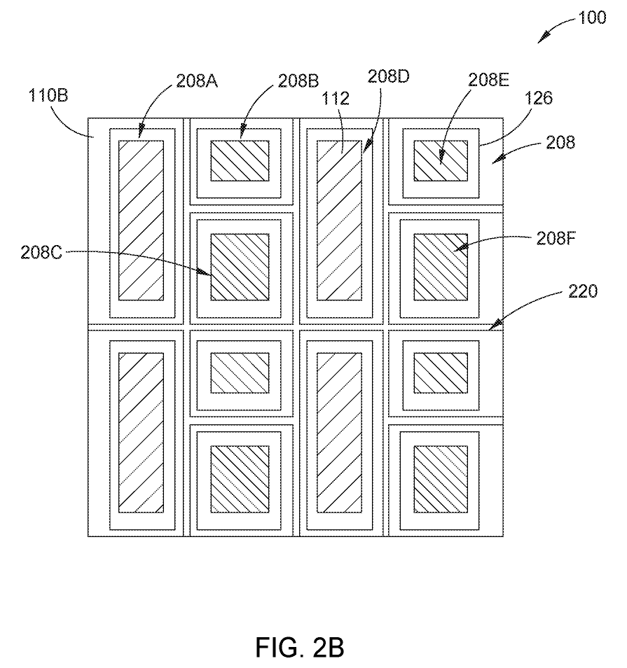

FIG. 1A is a cross‑sectional view of an organic light‑emitting diode (OLED) sub‑pixel circuit 100 formed on a backplane 102, taken along line A–A′ in the top view of FIG. 2A, according to one or more embodiments. The backplane 102 includes a drain supply line (V_{DD}) 105 and a source supply line (V_{SS}) 106. An anode 104 is disposed over the backplane 102 within each sub‑pixel opening 124. A via 108 extends from an upper surface 130 of the backplane 102 through backplane dielectric material and, to the drain supply line (V_{DD}) 105. The anode 104 includes an anode connection portion 122 received within the via 108 to electrically couple the anode 104 of each of the sub‑pixels 208A and 208D to the drain supply line (V_{DD}) 105. In one embodiment, the anode 104 comprises a multilayer stack including a first indium tin oxide (ITO) layer, a silver (Ag) layer, and a second ITO layer.

A plurality of pixel‑defining layer (PDL) structures 126 are disposed over the backplane 102. The PDL structures 126 laterally border the anode 104 and define the sub‑pixel opening 124 of each of the sub‑pixels 208A and 208D. The PDL structures 126 include one of an organic material, an organic material with an inorganic coating disposed thereover, or an inorganic material. Non‑limiting examples of organic material include polyimides. Non‑limiting examples of inorganic material include silicon oxide (SiO2), silicon nitride (Si3N4), silicon oxynitride, magnesium fluoride (MgF2), or combinations thereof.

Overhang structures 110 are disposed on upper surfaces of the PDL structures 126. Each overhang structure 110 includes a lower portion 110A and an upper portion 110B. The upper portion 110B is disposed over the lower portion 110A such that a bottom surface 109 of the upper portion 110B extends laterally past a top surface 111 of the lower portion 110A to form an overhang 115 on each side of the sub‑pixel opening 124. In one or more embodiments, the lower portion 110A is formed of a conductive metal material, such as molybdenum, and the upper portion 110B comprises a non‑conductive material. A via 128 extends through the PDL structure 126 and the backplane 102 to a driving thin film transistor (driving TFT) 150 that is coupled to the source supply line (V_{SS}) 106. A conductive connecting structure 123 is received within the via 128 and electrically couples the conductive lower portion 110A of the overhang structure 110 to the driving TFT 150, thereby providing a dedicated cathode routing path for each sub‑pixel. In the illustrated arrangement, a recess 220 is formed between neighboring overhang structures 110 to physically and electrically separate the overhang structures 110 of adjacent sub‑pixels, thereby maintaining isolation of the per‑pixel cathode routing described herein.

Within each sub‑pixel opening 124, the anode 104 is disposed over the backplane 102 and an organic light‑emitting (OLE) material 112 is disposed over the anode 104. The OLE material 112 includes one or more organic sub‑layers, such as a hole injection layer (HIL) 113, a hole transport layer (HTL), an emissive layer (EML), and an electron transport layer (ETL). A cathode 114 is disposed over the OLE material 112. In certain embodiments, the cathode 114 comprises a transparent or semi‑transparent conductive material, such as indium tin oxide (ITO) or indium zinc oxide (IZO), suitable for top‑emission operation; in other embodiments, a thin semi‑transparent metal or a metal/oxide stack may be used. In one or more embodiments, the cathode 114 includes a magnesium‑silver (MgAg) material.

In one or more embodiments, the cathode 114 is deposited at an angle relative to the overhang structures 110 so that the cathode 114 extends below the overhang 115 and contacts a sidewall 190 of the conductive lower portion 110A of at least one overhang structure 110. This sidewall 190 contact establishes an electrical coupling between the cathode 114 and the lower portion 110A. The coupled current path continues through the conductive connecting structure 123 within the via 128, which extends through both the PDL structure 126 and the backplane 102, to the terminal of the driving TFT 150. In this manner, the cathode 114 of each of the sub‑pixels 208A and 208D is individually routed to and driven by its corresponding driving TFT 150, while the anode 104 of each sub‑pixel is commonly tied to the drain supply line (V_{DD}) 105 through the anode connection portion 122 received within the via 108 that extends through the backplane 102. Each sub‑pixel 208 includes an encapsulation material 116 disposed over the cathode 114 and extending under at least a portion of the overhang structures 110 and along the sidewall 190; in some embodiments, a global encapsulation layer may be disposed over the overhang structures 110 and the encapsulation material 116.

In the illustrated embodiment, the per‑pixel routing described above permits the driving TFT 150 associated with each of the sub‑pixels 208A and 208D to directly regulate the current through the OLE material 112 at the cathode side while the anode 104 of each sub‑pixel remains commonly coupled to the drain supply line (V_{DD}) 105. Coupling the source terminal of the driving TFT 150 to the source supply line (V_{SS}) 106 stabilizes the gate‑to‑source operating point against OLED voltage drift, reducing image sticking and luminance non‑uniformity. The isolated overhang structures 110, the sidewall 190 contact, and the via‑based connections collectively provide robust electrical isolation and well‑defined routing paths that support compensation schemes and integration with n‑type oxide TFTs.

FIG. 1B is a schematic cross‑sectional view of a sub-pixel 208 of the organic light‑emitting diode (OLED) sub‑pixel circuit 100, according to one or more embodiments. In one or more embodiments, the backplane 102 includes a substrate 180, a buffer layer 182 disposed over the substrate 180, a passivation layer 184 disposed over the buffer layer 182, and a planarization layer 186 disposed over the passivation layer 184.

The driving thin film transistor (driving TFT) 150 is formed in and over the backplane 102. In one or more embodiments, the driving TFT 150 includes a gate electrode 152 disposed over the substrate 180. In one or more embodiments, the buffer layer 182 is disposed over the gate electrode 152. A semiconductor active layer 156 is disposed over the buffer layer 182. The semiconductor active layer 156 defines a channel region of the driving TFT 150 between a drain region D and a source region S. The drain region D is electrically coupled to the connecting structure 123. The source region S is electrically coupled to the source supply line (V_{SS}) 106. The passivation layer 184 is disposed over the driving TFT 150. A pixel-defining layer (PDL) structure 126 is disposed over the planarization layer 186 and defines a sub-pixel opening corresponding to the sub-pixel 208.

The via 128 extends through the pixel-defining layer (PDL) structure 126, the planarization layer 186, and the passivation layer 184 to provide electrical access to the driving TFT 150. The conductive connecting structure 123 is disposed within the via 128 and electrically couples the conductive lower portion 110A of the overhang structure 110 to the drain region D of the driving TFT 150. In one or more embodiments, the conductive connecting structure 123 comprises one or more conductive materials selected from metals or metal alloys and forms a vertical electrical interconnect between the overhang structure 110 and the driving TFT 150. In this manner, the cathode 114, which contacts the conductive lower portion 110A of the overhang structure 110, is electrically coupled to the drain region D of the driving TFT 150 through the connecting structure 123.

The anode 104 is disposed over the planarization layer 186 within the sub-pixel opening defined by the pixel-defining layer (PDL) structure 126. The anode connection via 108 extends through the planarization layer 186 and the passivation layer 184 to provide electrical access to the drain supply line (V_{DD}) 105 formed in the backplane 102. The anode connecting region 122 is disposed within the anode connection via 108 and electrically couples the anode 104 to the drain supply line (V_{DD}) 105. In one or more embodiments, the anode connecting region 122 comprises one or more conductive materials selected from metals or transparent conductive oxides. In this manner, the anode 104 of the sub-pixel 208 is commonly coupled to the drain supply line (VDD) 105 while the cathode 114 is individually driven by the driving TFT 150, thereby enabling a common-anode sub-pixel architecture.

FIG. 2A is a schematic top view of the sub-pixel circuit 100, according to one or more embodiments. Each sub-pixel 208 includes an OLE material bounded by a PDL structure 126 and an overhang structure 110 having an upper portion 110B. The overhang structure 110 surrounding each individual sub-pixel 208 is laterally separated from the overhangs of neighboring sub-pixels 208 by a recess 220 that extends between adjacent sub-pixel boundaries. The recess 220 provides electrical and physical isolation such that the overhang structure 110 associated with each sub-pixel (e.g., 208A, 208B, 208C, 208D, 208E, 208F) is non‑continuous across the array. For example, in one or more embodiments, the overhang structure 110 of the first sub-pixel 208A is separated from the overhang structures 110 of the adjacent second sub-pixel 208B by a first recess 220 and the overhang structure 110 of the first sub-pixel 208A is separated the separated from the overhang structures 110 of the adjacent fourth sub-pixel 208D by a second recess 220. In the illustrated arrangement, the recesses 220 extend in both the horizontal and vertical directions, partitioning the overhang structures 110 of each sub-pixel 208.

FIG. 2B is a top view of the sub-pixel circuit 100, according to one or more embodiments. Each sub-pixel 208 includes an OLE material 112 bounded by a pixel‑defining layer (PDL) structure 126 and an overhang structure having an upper portion 110B. The overhang structure 110 surrounding each sub-pixel is laterally separated from the overhangs of neighboring sub-pixels by a recess 220 that extends between adjacent sub-pixel boundaries. In one or more embodiments, the first sub-pixel 208A is shown with a larger organic light‑emitting material 112 region relative to the second sub-pixel 208B and the third sub-pixel 208C. A recess 220 physically and electrically separates the overhang structures 110 of each sub-pixel 208A-208C. In one or more embodiments, the first sub-pixel 208A emits a first color light. In one or more embodiments, the first color light is a blue light. In one or more embodiments, the second sub-pixel 208B emits a second color light. In one or more embodiments, the second color light is a green light. In one or more embodiments, the third sub-pixel 208C emits a third color light. In one or more embodiments, the third color light is a red light.

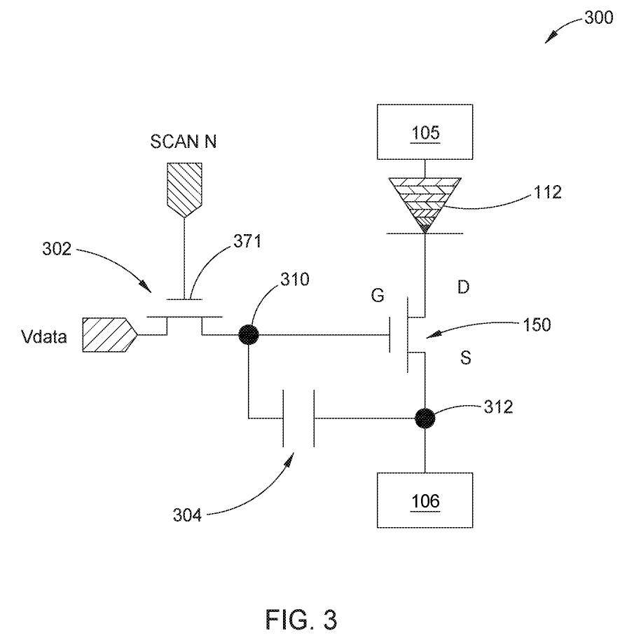

FIG. 3 is a schematic diagram of a sub-pixel drive circuit 300 suitable for use with the sub-pixel structures illustrated in FIGS. 1, 2A, and 2B, according to one or more embodiments. The sub-pixel drive circuit 300 includes a switching transistor 302 having a gate terminal 371 coupled to a scan line (Scan N), a first terminal coupled to a data line (V_{data}), and a second terminal coupled to a control node 310. A storage capacitor 304 is coupled between the control node 310 and a reference node 312. The driving transistor 150 includes the gate electrode 152 coupled to the control node 310, the drain region D coupled the drain supply line (V_{DD}) 105 and the source region S coupled to the source supply line (V_{SS}) 106. In operation, when a scan signal is applied to the scan line, the switching transistor 302 is placed in a conductive state to transfer a data voltage from the data line to the control node 310, thereby charging the storage capacitor 304. After the scan signal is removed, the switching transistor 302 is placed in a non-conductive state and the storage capacitor 304 maintains the control node voltage. The driving TFT 150 is thereby biased according to the stored voltage and conducts a drive current between the V_{DD} 105 and the V_{SS} 106. In one or more embodiments, the drive current is supplied to the OLE material 112 coupled between the driving TFT 150 and the V_{DD} 105, such that the luminance of the organic light-emitting device is determined by the stored voltage at the control node 310.

Benefits of the present disclosure include display devices and related methods that implement a common‑anode architecture in conjunction with per‑pixel cathode routing through electrically isolated overhang structures to improve drive stability and image quality. In one or more embodiments, the present disclosure provides reduced image sticking and luminance non‑uniformity by stabilizing the gate‑to‑source operating point of a driving thin film transistor referenced to V_{SS} while decoupling the drive point from OLED voltage drift at the cathode. Benefits of the present disclosure further include mitigation of IR drop and interconnect congestion by consolidating hole‑injection distribution onto a robust V_{DD} common anode line, improved grayscale accuracy and compensation efficacy through individualized cathode control paths compatible with n‑type oxide TFTs, and maintenance of device efficiency and lifetime by preserving a non‑inverted OLED stack (e.g., ITO/Ag/ITO anode and MgAg or transparent cathode) without requiring FMM inversion. Collectively, these features can yield enhanced panel uniformity, reduced noise coupling and drift sensitivity, improved long‑term reliability and yield, and manufacturing flexibility across pixel layouts (e.g., strip and S‑strip) while maintaining precise deposition control under permanent overhangs.

While the foregoing is directed to examples of the present disclosure, other and further examples of the disclosure may be devised without departing from the basic scope thereof, and the scope thereof is determined by the claims that follow.

What is claimed is:

1. A display device comprising:
a backplane having a drain supply line (V_{DD}) and a source supply line (V_{SS}); and
overhang structures disposed over the backplane, adjacent overhang structures defining sub-pixels of the device;
a plurality of sub-pixels disposed on the backplane, each sub-pixel comprising:
a thin film transistor circuit including a driving thin film transistor (driving TFT);
an anode disposed on the backplane and electrically coupled to the drain supply line (V_{DD}) via a common anode interconnect;
an organic light-emitting (OLE) material disposed over the anode; and
a cathode disposed over the OLE material, wherein the cathode is electrically coupled to the driving TFT through a conductive connecting structure that extends through one or more dielectric layers of the backplane and is electrically coupled to a conductive portion of one of the overhang structures, such that the driving TFT individually drives the cathode of the sub-pixel.

2. The display device of claim 1, wherein each overhang structure comprises:
a first structure disposed over the backplane, the first structure including an upper surface; and
a second structure disposed over the upper surface of the first structure, a bottom surface of the second structure extending laterally past the upper surface of the first structure.

3. The display device of claim 2, wherein the first structure comprises a metal material.

4. The display device of claim 3, wherein the first structure comprises a molybdenum material.

5. The display device of claim 1, wherein the overhang structures of different sub-pixels are electrically isolated from one another.

6. The display device of claim 1, wherein a recess separates the overhang structures of adjacent sub-pixels.

7. The display device of claim 1, wherein each overhang structure is disposed over a pixel-defining layer (PDL) structure disposed over the backplane, wherein the PDL structure is disposed between adjacent sub-pixels.

8. The display device of claim 1, wherein a source terminal of the driving TFT is coupled to V_{SS} a drain terminal of the driving TFT is coupled to the cathode, and a gate terminal of the driving TFT is coupled to a switching TFT.

9. The display device of claim 1, further comprising an encapsulation material disposed over the cathode.

10. A sub-pixel drive circuit comprising:
a scan line;
a data line;
a switching transistor having a gate terminal coupled to the scan line, a first terminal coupled to the data line, and a second terminal coupled to a control node;
a source supply line (V_{SS});
a drain supply line (V_{DD}); and
a driving transistor having a gate terminal coupled to the control node, a source terminal coupled to the V_{SS} and a drain terminal coupled to the V_{DD}.

11. The sub-pixel drive circuit of claim 10, further comprising a storage capacitor coupled between the control node and a reference node.

12. The sub-pixel drive circuit of claim 10, further comprising an organic light-emitting (OLE) material disposed between the driving transistor and the V_{DD}.

13. A display device comprising:
a backplane having a drain supply line (V_{DD}) and a source supply line (V_{SS}); and
overhang structures disposed over the backplane, adjacent overhang structures defining sub-pixels of the device;
a first sub-pixel comprising:
a first driving thin film transistor (driving TFT);
a first anode disposed on the backplane and electrically coupled to the drain supply line (V_{DD}) via a common anode interconnect;
a first organic light-emitting (OLE) material disposed over the first anode; and
a first cathode disposed over the OLE material; wherein the cathode is electrically coupled to the first driving TFT; and
a second sub-pixel comprising:
a second driving thin film transistor (driving TFT);
a second anode disposed on the backplane and electrically coupled to the drain supply line (V_{DD}) via a common anode interconnect;
a second organic light-emitting (OLE) material disposed over the second anode; and
a second cathode disposed over the second OLE material, wherein the second cathode is electrically coupled to the second driving TFT.

14. The display device of claim 13 further comprising a recess separating the adjacent overhang structures defining each sub-pixel.

15. The display device of claim 13, wherein each overhang structure comprises:
a first structure disposed over the backplane, the first structure including an upper surface; and
a second structure disposed over the upper surface of the first structure, a bottom surface of the second structure extending laterally past the upper surface of the first structure.

16. The display device of claim 15, wherein the first structure comprises a metal material.

17. The display device of claim 16, wherein the first structure comprises a molybdenum material.

18. The display device of claim 13, wherein the overhang structures of different sub-pixels are electrically isolated from one another.

19. The display device of claim 13, wherein each overhang structure is disposed over a pixel-defining layer (PDL) structure disposed over the backplane, wherein the PDL structure is disposed between adjacent sub-pixels.

20. The display device of claim 13, wherein a source terminal of the driving TFT is coupled to V_{SS} a drain terminal of the driving TFT is coupled to the cathode, and a gate terminal of the driving TFT is coupled to a switching TFT.
